(19) United States
(12) Patent Application Publication
(10) Pub. No.: US 2024/0160117 A1
(43) Pub. Date: May 16, 2024

(54) PROCESS CELL FOR FILED GUIDED POST EXPOSURE BAKE PROCESS

(71) Applicant: Applied Materials, Inc., Santa Clara, CA (US)

(72) Inventors: Dmitry LUBOMIRSKY, Cupertino, CA (US); Kyle M. HANSON, Kalispell, MT (US); Douglas A. BUCHBERGER, Jr., Livermore, CA (US); Alan L. TSO, San Jose, CA (US); Rahul KOZHIKKALKANDI, Bangalore (IN); Paul R. MCHUGH, Santa Clara, CA (US); Jiayi SUN, Santa Clara, CA (US); Qiwei LIANG, Fremont, CA (US); Nithin Thomas ALEX, Bangalore (IN); Lancelot HUANG, Santa Clara, CA (US); Ellie Y. YIEH, San Jose, CA (US)

(73) Assignee: Applied Materials, Inc., Santa Clara, CA (US)

(21) Appl. No.: 18/282,509

(22) PCT Filed: Apr. 2, 2021
(86) PCT No.: PCT/CN2021/085424

§ 371 Date: Sep. 15, 2023

(51) Int. Cl. G03F 7/00; G03F 7/40

(52) U.S. Cl. CPC G03F 7/70875; G03F 7/40; G03F 7/707; G03F 7/70758

(57) ABSTRACT

Apparatus and method for substrate processing are described herein. More specifically, the apparatus and method are directed towards apparatus and method for performing a field guided post exposure bake operation on a semiconductor substrate. The apparatus is a processing module (100) and includes an upper portion (102) with an electrode (400) and a base portion (104) which is configured to support a substrate (500) on a substrate support surface (159). The upper portion (102) and the base portion (104) are actuated toward and away from one another using one or more arms (112) and form a process volume (404). The process volume (404) is filled with a process fluid and the processing module (100) is rotated about an axis (A). An electric field is applied to the substrate (500) by the electrode (400) before the process fluid is drained from the process volume (404).

### BACKGROUND

### Field

The present disclosure generally relates to methods and apparatus for processing a substrate, and more specifically to methods and apparatus for improving patterning processes.

### Description of the Related Art

Integrated circuits have evolved into complex devices that can include millions of components (e.g., transistors, capacitors and resistors) on a single chip. Photolithography is a process that may be used to form components on a chip. Generally the process of photolithography involves a few basic stages. Initially, a photoresist layer is formed on a substrate. A chemically amplified photoresist typically includes a resist resin and a photoacid generator. The photoacid generator, upon exposure to electromagnetic radiation in a subsequent exposure stage, alters the solubility of the photoresist in the development process. The electromagnetic radiation may have any suitable wavelength, for example, a 193 nm ArF laser, or be an electron beam, an ion beam, or other suitable electromagnetic radiation source.

In the exposure stage, a photomask or reticle is used to selectively expose certain regions of the substrate to electromagnetic radiation. Other exposure methods include maskless exposure methods or the like. Exposure to light decomposes the photo acid generator, which generates acid and results in a latent acid image in the resist resin. After exposure, the substrate is heated in a post-exposure bake process. During the post-exposure bake process, the acid generated by the photoacid generator reacts with the resist resin, changing the solubility of the resist during the subsequent development process.

After the post-exposure bake, the substrate, particularly the photoresist layer, is developed and rinsed. Depending on the type of photoresist used, regions of the substrate that were exposed to electromagnetic radiation are either resistant to removal or more prone to removal. After development and rinsing, the pattern of the mask is transferred to the substrate using a wet or dry etch process.

The evolution of chip design continually pursues faster circuitry and greater circuit density. The demand for greater circuit density typically utilizes a reduction in the dimensions of the integrated circuit components. As the dimensions of the integrated circuit components are reduced, more elements are able to be placed in a given area on a semiconductor integrated circuit. Accordingly, lithography processes transfer even smaller features onto a substrate, and lithography does so precisely, accurately, and without damage to meet advanced chip design specifications. In order to precisely and accurately transfer features onto a substrate, high resolution lithography utilizes a light source that provides radiation at small wavelengths. Small wavelengths help to reduce the minimum printable size on a substrate or wafer. However, small wavelength lithography suffers from problems, such as low throughput, increased line edge roughness, and/or decreased resist sensitivity.

Electrode assemblies are utilized to generate and deliver an electric field to a photoresist layer disposed on the substrate prior to or after an exposure process so as to modify chemical properties of a portion of the photoresist layer where the electromagnetic radiation is transmitted for improving lithography exposure/development resolution. However, the challenges in implementing such systems have not yet been adequately overcome. For example, differences in electric field strength across the photoresist layer may cause non-uniformities in acid generation and deprotection rates, which adversely impact patterning of the substrate.

Therefore, there is a need for improved methods and apparatus for field guided post exposure bake processes.

### SUMMARY

In one embodiment, a substrate processing apparatus is described. The substrate processing apparatus includes a support plate, a base portion disposed on top of the support plate, an upper portion, and a plurality of arms connecting the upper portion and the base portion. The base portion includes a base body, a substrate support plate disposed within the base body, a substrate support surface on the substrate support plate, one or more bearings coupled to the base body and configured to rotate the base body about an axis, and an actuator coupled to the base body and the support plate. The upper portion is disposed above the base portion and the support plate. The upper portion includes an electrode and a lid disposed above the electrode.

In another embodiment, a substrate processing apparatus is described. The substrate processing apparatus includes a support plate, a substrate processing module, an actuator, one or more bearings, and a fluid inlet. The substrate processing module includes a base portion, an upper portion, and a plurality of arms connection the upper portion and the base portion. The base portion is disposed on top of the support plate and includes a base body, a substrate support plate disposed within the base body, and a substrate support surface on the substrate support plate. The upper portion is disposed above the base portion and the support plate and includes an electrode with a bottom surface disposed parallel to the substrate support surface and a lid disposed above the electrode. The actuator is coupled to the base body and the support plate. The one or more bearings are coupled to the base body and configured to rotate the base body about an axis as the actuator moves the base body. The fluid inlet is disposed through the base body.

In yet another embodiment, a method of processing a substrate is described. The method includes position a substrate onto a substrate support plate while the substrate support plate is in a first position, moving an electrode towards the substrate support plate to form a process volume around the substrate and between the electrode and the substrate support plate, pumping a backside of the substrate to a first backside pressure, rotating the process volume about a rotation axis to a process position using an actuator, and pumping a backside of the substrate to a second backside pressure less than the first backside pressure. After rotating the process volume to the process position and pumping the backside of the substrate to the second backside pressure a process fluid is supplied to the process volume from a fluid inlet. An electric field is applied to the substrate using the electrode while in the process position and the process fluid is drained from the process volume while in the process position.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic front view of a substrate processing module according to one embodiment described herein.

FIG. 2 illustrates a schematic side view of the substrate processing module of FIG. 1 according to one embodiment described herein.

FIG. 3A illustrates a schematic plan view of the substrate processing module of FIG. 1 according to one embodiment described herein.

FIG. 3B illustrates a schematic plan view of the substrate processing module of FIG. 1 according to another embodiment described herein.

FIG. 4 illustrates a schematic cross-sectional view of the substrate processing module of FIG. 1 through a first plane according to one embodiment described herein.

FIG. 5A illustrates a schematic cross-sectional view of the substrate processing module of FIG. 1 through a second plane during a process operation according to one embodiment described herein.

FIG. 5B illustrates a schematic cross-sectional view of the substrate processing module of FIG. 1 through a second plane during another process operation according to one embodiment described herein.

FIG. 5C illustrates a schematic cross-sectional view of the substrate processing module of FIG. 1 through a second plane during yet another process operation according to one embodiment described herein.

FIG. 5D illustrates a schematic cross-sectional view of the substrate processing module of FIG. 1 through a second plane during yet another process operation according to one embodiment described herein.

FIG. 5E illustrates a schematic cross-sectional view of the substrate processing module of FIG. 1 through a second plane during yet another process operation according to one embodiment described herein.

FIG. 5F illustrates a schematic cross-sectional view of the substrate processing module of FIG. 1 through a second plane during yet another process operation according to one embodiment described herein.

FIG. 6 illustrates a schematic cross-sectional view of the substrate processing module of FIG. 1 through a third plane according to one embodiment described herein.

FIG. 7A illustrates a schematic cross-sectional view of a substrate support plate for use with the substrate processing module of FIG. 1 according to one embodiment described herein.

FIG. 7B is a plan view of a substrate support plate for use with the substrate processing module of FIG. 1 according to one embodiment described herein.

FIG. 8 is a schematic side view of a stacked assembly of substrate processing modules according to one embodiment described herein.

FIG. 9A illustrates operations of a method for performing an immersion post exposure bake process according to an embodiment described herein.

FIG. 9B illustrates operations of the method for performing an immersion post exposure bake process of FIG. 9B according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to methods and apparatus for post exposure bake processes. Methods and apparatus disclosed herein assist in reducing line edge/width roughness and improving exposure resolution in a photolithography process for semiconductor applications.

The methods and apparatus disclosed herein improve the photoresist sensitivity and productivity of photolithography processes. The random diffusion of charged species generated by a photoacid generator during a post exposure bake procedure contributes to line edge/width roughness and reduced resist sensitivity. An electrode assembly, such as those described herein, is utilized to apply an electric field and/or a magnetic field to the photoresist layer during photolithography processes. The field application controls the diffusion of the charged species generated by the photoacid generator. Furthermore, an intermediate medium is utilized between the photoresist layer and the electrode assembly so as to enhance the electric field generated therebetween.

An air gap defined between the photoresist layer and the electrode assembly results in voltage drop applied to the electrode assembly, thus, adversely lowering the electric field strength applied to the photoresist layer. A non-uniform electric field at the photoresist layer may result in insufficient or inaccurate voltage power to drive or otherwise influence charged species in the photoresist layer in certain desired directions, thus leading to diminished line edge profile control to the photoresist layer. Thus, an intermediate medium is placed between the photoresist layer and the electrode assembly to prevent an air gap from being created therebetween so as to maintain suitable strength and uniformity of the electric field interacting with the photoresist layer.

The charged species generated by the electric field are guided in a desired direction along the line and spacing direction, substantially preventing the line edge/width roughness that results from inaccurate and random diffusion. Thus, the electric field is well controlled to maintain field strength and uniformity which increases the accuracy and sensitivity of the photoresist layer during the post exposure development processes. In one example, the intermediate medium is a non-gas phase medium, such as a slurry, gel, liquid solution, or a solid state medium that efficiently maintains voltage levels as applied at a determined range when transmitting from the electrode assembly to the photoresist layer disposed on the substrate.

Even while using the intermediate medium, a voltage drop is still present between the photoresist layer and the electrode assembly. This voltage drop is directly related to the distance between the photoresist layer and the electrode assembly. Reducing the distance between the photoresist layer and the electrode assembly assists in improving the uniformity of the electric field between the photoresist layer and the electrode assembly. Another consideration while using the intermediate medium is the presence of gas bubbles between the photoresist layer and the electrode assembly. Bubbling and the formation of air pockets between the photoresist layer and the electrode assembly causes non-uniformities within the electric field and therefore increases the number of defects and inaccuracies within the photoresist after the post-exposure bake process. The apparatus and methods described herein for reducing the distance between the photoresist and the electrode assembly beneficially reduce the number of bubbles or air pockets between the photoresist layer and the electrode assembly.

The embodiments additionally reduce the vertical footprint of the assembly and enable vertical stacking of process modules. Reducing the vertical footprint is enabled, at least in part, by horizontal loading and unloading of the substrate to and from the process modules. The orientation (angle of the process modules relative to a horizontal plane) of the assembly during processing is also controlled to reduce the effects of bubbling, while reducing the vertical footprint. It has been found that a processing angle of greater than about 5 degrees from a horizontal substantially reduces the amount of bubbles between the electrode and the substrate after filling the process volume. An angle of less than about 60 degrees or about 50 degrees has been shown to enable vertical stacking of the assembly within system architectures.

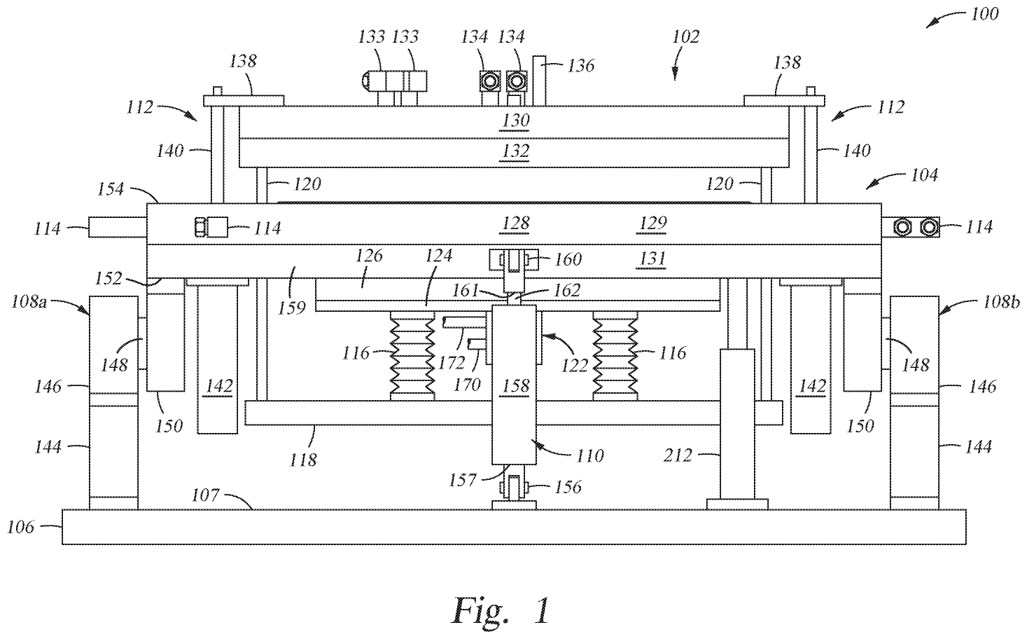

FIG. 1 illustrates a schematic front view of a substrate processing module 100 according to one embodiment described herein. The substrate processing module 100 includes a support plate 106, a base portion 104 disposed on top of the support plate 106, and an upper portion 102 disposed above the base portion 104 and the support plate 106. The base portion 104 and the upper portion 102 are configured to be moved during processing of substrates within the substrate processing module 100. The base portion 104 is coupled to the support plate 106 by one or more bearing assemblies 108a, 108b. The bearing assemblies 108a, 108b are disposed on the sides of the base portion 104 and are configured to enable rotation of the base portion 104 and the upper portion 102. In one embodiment, the bearing assemblies 108a, 108b are coupled to the base portion 104 opposite one another.

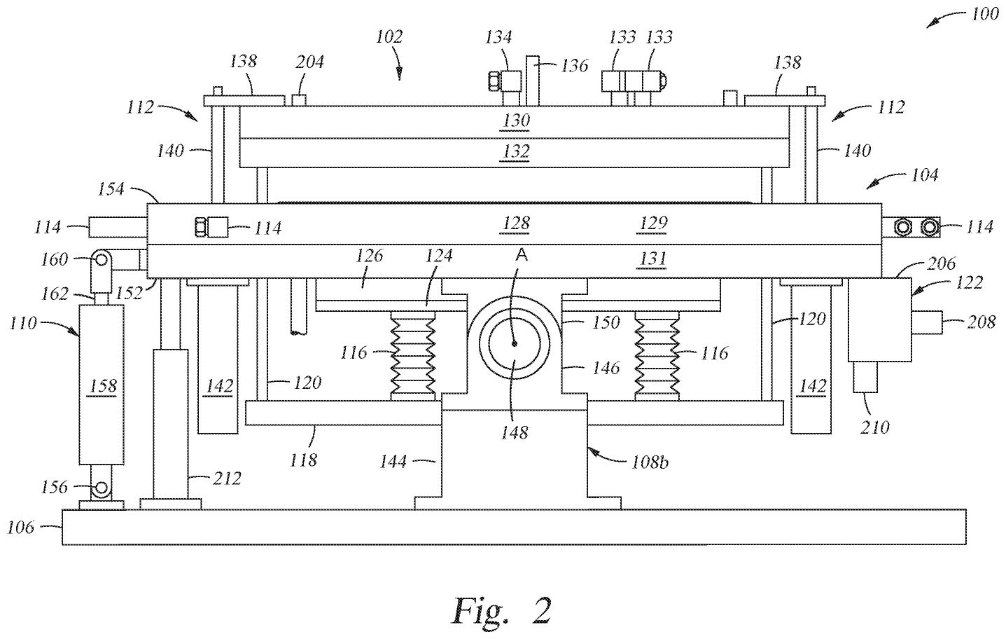

An actuator 110 is coupled to a surface 159 of the base portion 104 and the support plate 106. The actuator 110 is configured to impart force onto the base portion 104 and cause the base portion 104 and the upper portion 102 to move in a tipping motion about an axis A (FIG. 2). A portion of a fluid supply assembly 122 is shown on the opposite side of the base portion 104 from the actuator 110. The fluid supply assembly 122 is configured to supply and remove fluid, such as a liquid or processing medium, to/from the substrate processing module 100.

As shown in FIG. 1, the base portion 104 includes a base body 128. A plurality of arms 112 connect the base portion 104 and the upper portion 102. The plurality of arms 112 are configured to pass through the base body 128 and connect to the upper portion 102. The plurality of arms 112 include an arm actuator 142 disposed below the base body 128 and a shaft 140 disposed through a portion of the arm actuator 142 and the base body 128. The shaft 140 is coupled to the upper portion 102 and configured to raise or lower the upper portion 102 with respect to the base body 128. As shown in FIG. 1, the shaft 140 is coupled to the upper portion 102 using a fastener 138. The fastener 138 connects the shaft 140 to a lid 130 of the upper portion 102. In other embodiments, the fastener 138 connects the shaft 140 to a spacer plate 132 disposed below the lid 130. The fastener 138 may be a clasp, a clamp, a buckle, a bolt, a screw, or other suitable connecting apparatus. In some embodiments, the fastener 138 includes multiple components, such as a nut and a bolt or a second shaft extending from the shaft 140 to the upper portion 102.

The arm actuator 142 is an actuator mechanism configured to raise and lower the shaft 140. The arm actuator 142 described herein is a pneumatic actuator, but could also be a motor, such as an electric motor. The arm actuator 142 is disposed below the base body 128 to prevent obstruction of the opening between the upper portion 102 and the lower portion 104. In one embodiment, the arm actuator 142 is disposed between the base body 128 and the support plate 106. Arm actuator coolant connections 114 are coupled to the base body 128 and/or the arm actuator 142. The arm actuator coolant connections 114 are configured to enable coolant lines to be coupled to the lower portion 104. The arm actuator coolant connections 114 are configured to cool the arm actuators 142 by receiving fluid from a fluid source and circulating fluid through a conduit disposed around or adjacent to the arm actuators 142.

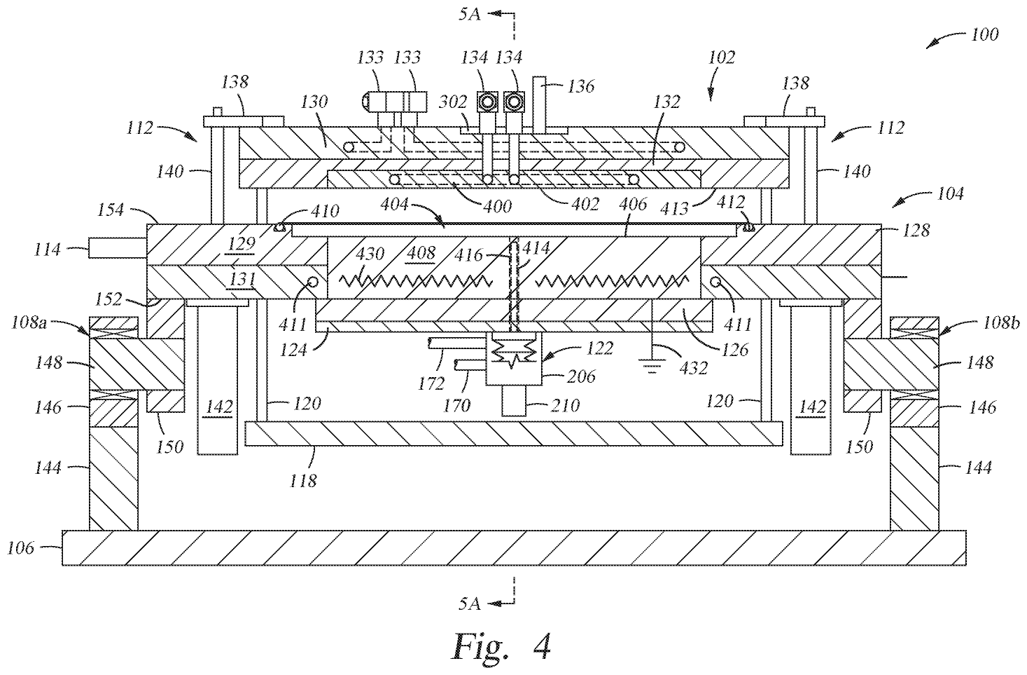

The base body 128 includes a temperature control plate 131 and a dielectric plate 129. The dielectric plate 129 is disposed on top of the temperature control plate 131. In one embodiment, the dielectric plate 129 is coupled to and in contact with the temperature control plate 131. The dielectric plate 129 is fabricated from a polymer material, such as a fluoropolymer or a polyaryletherketone (PAEK) polymer material. In some embodiments, the dielectric plate 129 is polyether ether ketone (PEEK) or polytetrafluoroethylene polymer material. In other embodiments, the dielectric plate 129 is fabricated from a ceramic material, such as an aluminum oxide (Al₂O₃), aluminum nitride (AlN), or yttrium oxide (Y₂O₃). The temperature control plate 131 is fabricated from a metal material. The metal material includes any one or a combination of aluminum, stainless steel, nickel, copper, or an alloy thereof. In some embodiments, the arm actuator coolant connections 114 are coolant connections for the base body 128 and cooling channels 411 (FIG. 4) are formed therethrough to enable temperature control of the temperature control plate 131.

The upper portion 102 includes an electrode 400 (FIG. 4), the lid 130, and the spacer plate 132. The lid 130 is disposed above the spacer plate 132. In one embodiment, the lid 130 is coupled to and disposed in contact with the spacer plate 132. The spacer plate 132 is disposed between the lid 130 and the base body 128. The lid 130 is configured to support the electrode 400 and the spacer plate 132. The lid 130 is fabricated from a metal material. The metal material includes any one or a combination of aluminum, stainless steel, nickel, copper, or an alloy thereof. The spacer plate 132 is disposed on or otherwise coupled to a bottom of the lid 130. The spacer plate 132 is a dielectric or a ceramic material. The spacer plate 132 functions to separate the lid 130 and the electrode 400 from a top surface 154 of the base body 128. In some embodiments, the spacer plate 132 is fabricated from a polymer material, such as a fluoropolymer or a polyaryletherketone (PAEK). In some embodiments, the spacer plate 132 is polyether ether ketone (PEEK) plastic or polytetrafluoroethylene material. In other embodiments, the spacer plate 132 is fabricated from a ceramic material, such as an aluminum oxide (Al₂O₃), aluminum nitride (AlN), or yttrium oxide (Y₂O₃).

Electrode cooling fluid connections 134 are disposed on top of the lid 130. The electrode cooling fluid connections 134 enable a coolant line, such as water supply and removal lines, to be connected to the upper portion 102. The electrode cooling fluid connections 134 include an inlet and an outlet. The electrode cooling fluid connections 134 connect to a conduit within the electrode 400 (FIG. 4). The conduit is disposed through the electrode 400 to enable temperature regulation of the electrode 400. Lid cooling fluid connections 133 are additionally disposed on top of the lid 130. The lid cooling fluid connections 133 are configured to enable a second coolant line, such as water supply and removal lines, to be connected to the upper portion 102. The lid cooling fluid connections 133 include an inlet and an outlet. The lid cooling fluid connections 133 are fluidly connected to a conduit within the lid 130 (FIG. 4).

An electrode connection 136 is disposed on top of the lid 130 and extending through the lid 130 and a portion of the spacer plate 132 to electrically couple the electrode connection 136 to the electrode 400 (FIG. 4). The electrode connection 136 is configured to couple to a power source, such as a voltage generator or a current generator. The electrode connection 136 is configured to be coupled to either a DC or an AC power source. The electrode connection 136 may be either a male or female electrical connection.

A base bottom plate 124 is disposed below the base body 128. The base bottom plate 124 is also disposed below a chuck isolation plate 126. The base bottom plate 124 is a metal material, such that the base bottom plate 124 includes any one or a combination of aluminum, stainless steel, nickel, copper, or an alloy thereof. The chuck isolation plate 126 is a dielectric or a ceramic material. In one embodiment, the chuck isolation plate 126 is a similar material to the spacer plate 132, such as a polymer, for example, a fluoropolymer or a polyaryletherketone (PAEK) material. In some embodiments, the chuck isolation plate 126 is polyether ether ketone (PEEK) or polytetrafluoroethylene. In other embodiments, the chuck isolation plate 126 is a ceramic material, such as aluminum oxide (Al₂O₃), aluminum nitride (AlN), yttrium oxide (Y₂O₃), or combinations thereof. The chuck isolation plate 126 electrically and thermally isolates a substrate support plate 408 (FIG. 4) within the base body 128 from the base bottom plate 124. The chuck isolation plate 126 is disposed between the substrate support plate 408 and the base bottom plate 124. The base bottom plate 124 provides structural support to the chuck isolation plate 126 and the substrate support plate 408. The base bottom plate 124 and chuck isolation plate 126 are mechanically coupled to the bottom of the base body 128. The base bottom plate 124 may additionally have one or more bellows 116 attached to the bottom surface thereof. The bellows 116 are configured to surround a plurality of lift pins 416 (FIG. 4), which are disposed through the base bottom plate 124, the chuck isolation plate 126, and the substrate support plate 408.

The plurality of lift pins 416 are disposed above a lift pin plate 118. Each of the bellows 116 is disposed between the lift pin plate 118 and the base bottom plate 124. The bellows 116 surround and form a seal around each of the lift pins 416. The bellows 116 are a flexible material and may expand and contract as the lift pin plate 118 is raised and lowered with respect to the base body 128. The lift pin plate 118 is mechanically coupled to the upper portion 102 by a plurality of connection rods 120. The connection rods 120 extend from the lift pin plate 118 through the base body 128 to the upper portion 102. The connection rods 120 are mechanically connected to each of the lift pin plate 118 and at least one of the lid 130 or the spacer plate 132 of the upper portion 102. In embodiments described herein, the connection rods 120 are disposed radially inward of the shafts 140 of the arms 112.

Each of the bearing assemblies 108a, 108b is configured to enable rotation of the base portion 104 and the upper portion 102 around an axis A (FIG. 2). The bearing assemblies 108a, 108b include a first bearing assembly 108a and a second bearing assembly 108b. Each one of the bearing assemblies 108a, 108b includes a housing 146 and a shaft 148. The shaft 148 is disposed through the housing 146 and is configured to rotate within the housing 146. The shaft 148 is a cylindrical shaft, or other suitable shape, and is coupled to the housing 146 via a plurality of ball bearings and sealing rings (not shown). Each of the first bearing assembly 108a and the second bearing assembly 108b are pillow block bearings. Other types of bearing assemblies may be utilized in addition to or in place of the pillow block bearings.

The housing 146 of each of the bearing assemblies 108a, 108b is disposed on top of a bearing pedestal 144. Each of the two bearing pedestals 144 is disposed below the housings 146 to raise the bearing assemblies 108a, 108b to a height that enables sufficient rotation of the substrate processing module 100 without contacting the support plate 106. The housing 146 of each of the first bearing assembly 108a and the second bearing assembly 108b is mechanically coupled to one of the bearing pedestals 144. The bearing pedestals 144 are mechanically coupled to and disposed on top of the support plate 106.

The shaft 148 of the first bearing assembly 108a and the shaft 148 of the second bearing assembly 108b are coupled to a base housing 150. The base housing 150 is coupled to a bottom surface 152 of the base body 128. The base housing 150 is configured to couple the shaft 148 and the base body 128. The base housing 150 is fixedly coupled to the shaft 148, such that the shaft 148 does not move within the base housing 150. The shaft 148 being fixed within the base housing 150 enables the base body 128 to be rotated along with the rotation of the shaft 148. Each of the first bearing assembly 108a and the second bearing assembly 108b is disposed on opposite sides of the base body 128, such that the central axis of each of the shafts 148 are collinear. The single axis of rotation enables the base body 128 to be actuated around a pivot in a tilting motion.

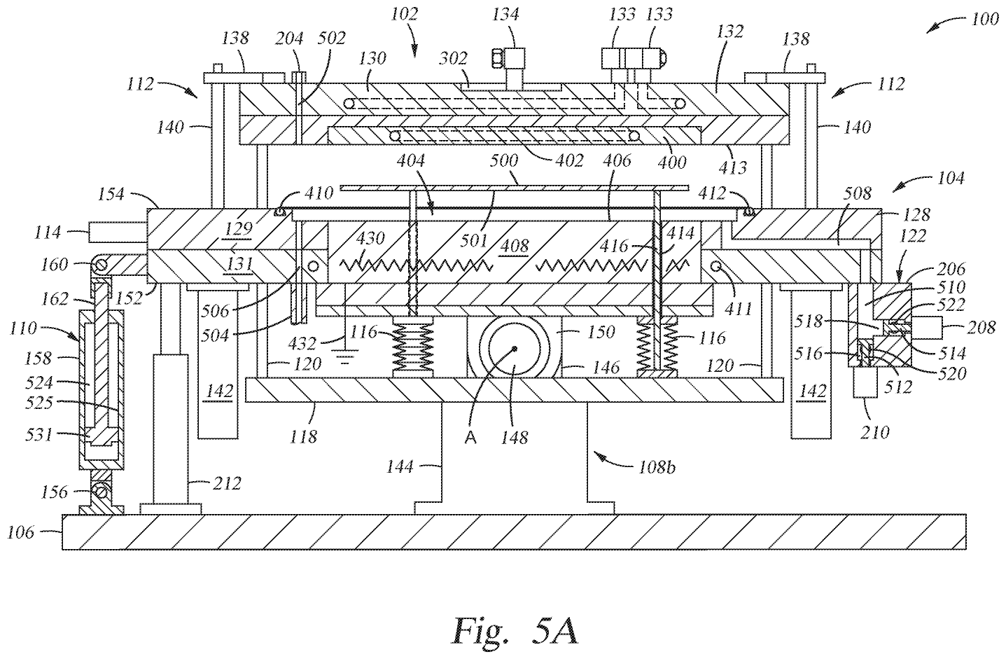

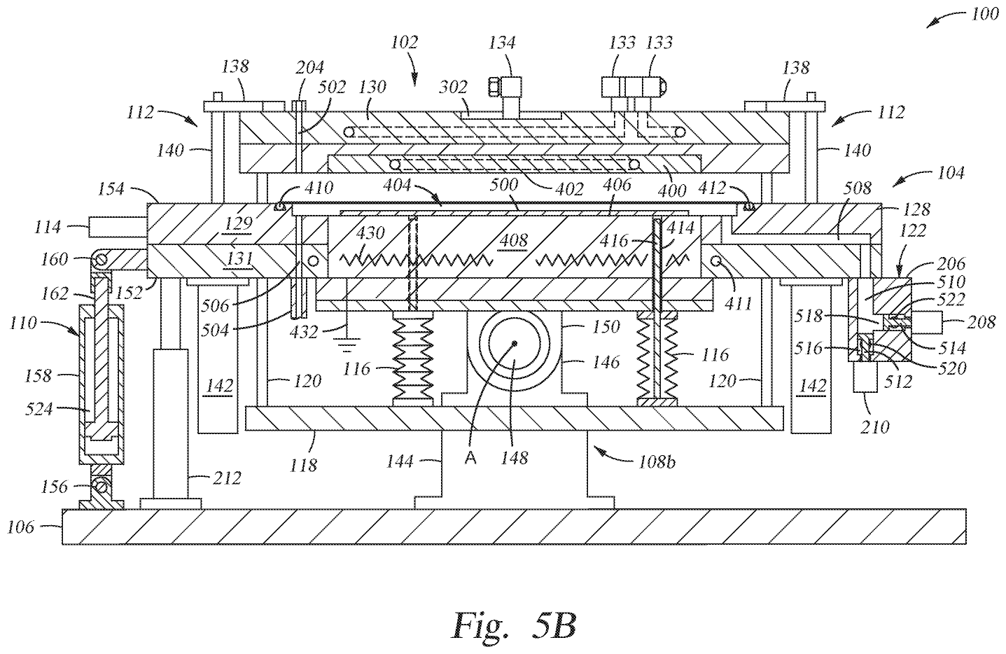

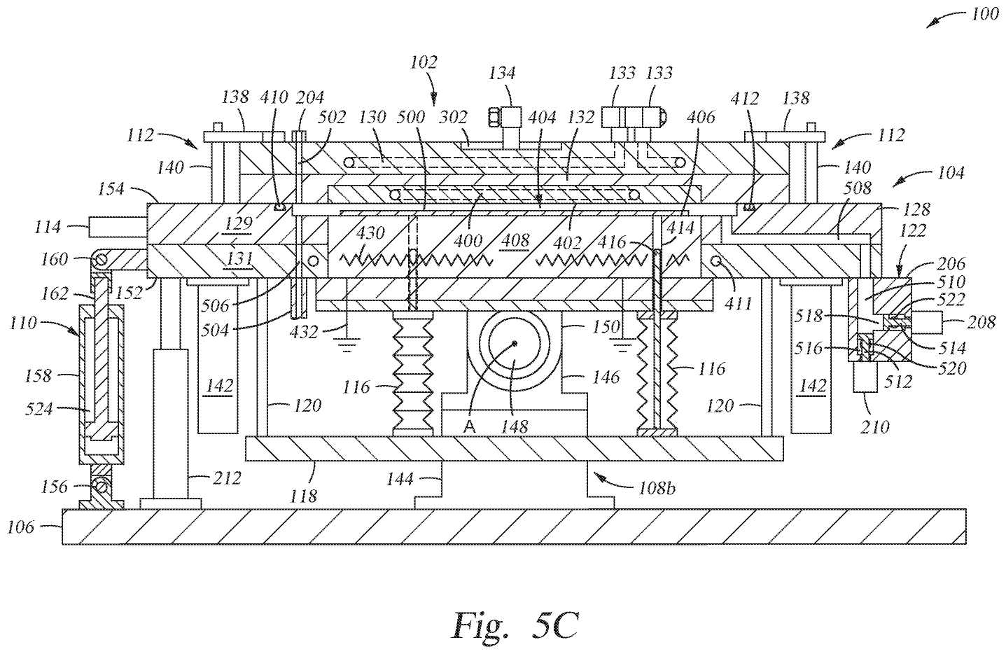

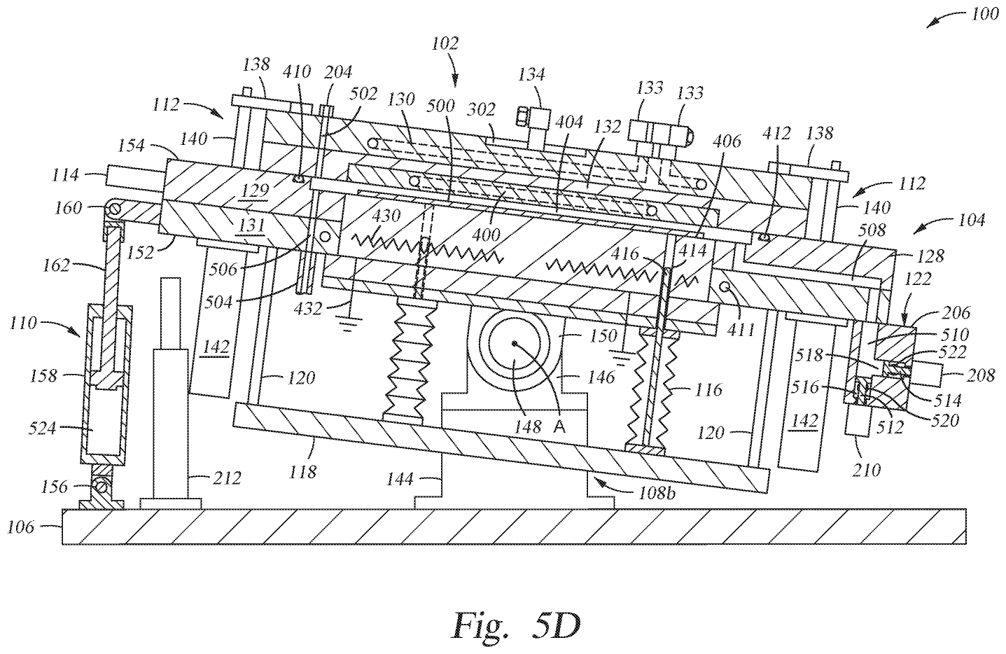

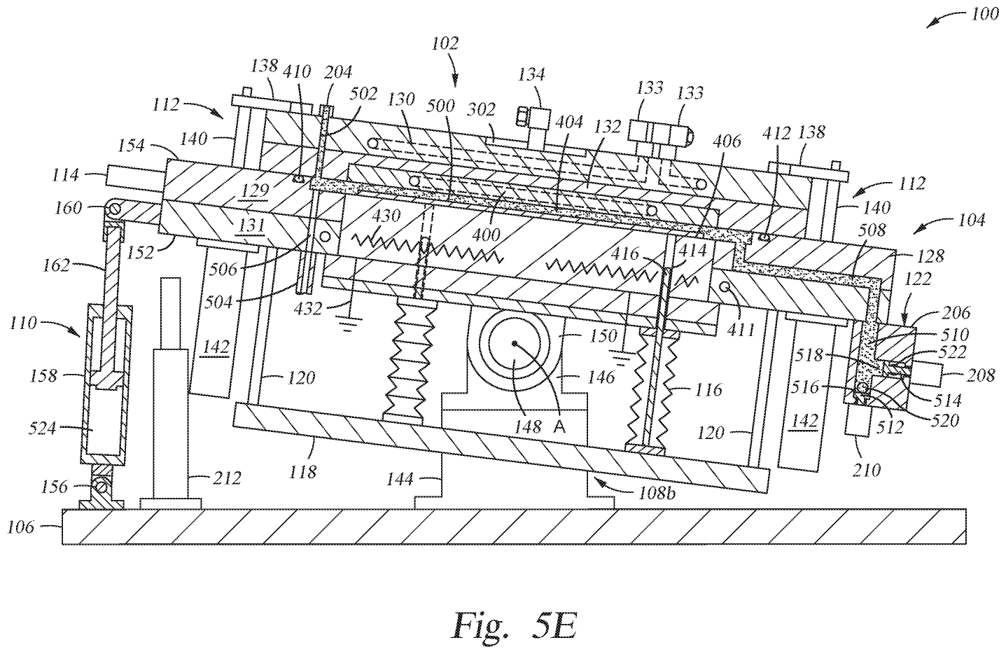

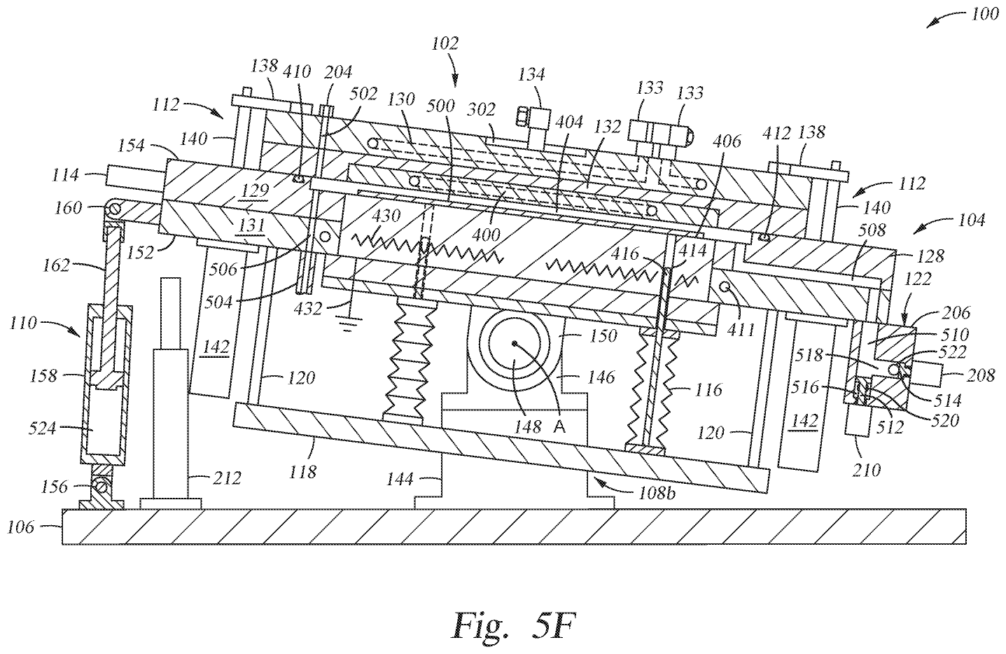

The actuator 110 is coupled to the top surface 107 of the support plate 106 and a surface 159 of the base body 128. The actuator 110 includes a lower hinge 158 which is coupled to and disposed on the support plate 106. A piston 158 is coupled at one end 157 to the lower hinge 158. An actuator shaft 162 is disposed at least partially within the piston 158. An upper hinge 160 is coupled to a distal end 161 of the actuator shaft 162 and the surface 159 of the base body 128. The lower hinge 158 is coupled to the support plate 106 and the piston 158. The lower hinge 158 enables the piston 158 to move about a lower hinge axis. The piston 158 is a cylindrical shaft and includes an opening 524 (FIG. 5A) through which the actuator shaft 162 is disposed. The actuator shaft 162 is configured to move within the piston 158 to actuate the base body 128. A top distal end 161 of the actuator shaft 162 is coupled to the upper hinge 128. The upper hinge 128 connects the actuator shaft 162 and the base body 128. The upper hinge 128 enables the actuator shaft 162 and the base body 128 to move with respect to one another around an upper hinge axis.

The fluid supply assembly 122 is disposed on an opposite side of the base body 128 from the actuator 110. The fluid supply assembly 122 includes a fluid supply connection 170 and a fluid drain connection 172. The fluid supply connection 170 is configured to be attached to a process fluid conduit (not shown) and introduces process fluid to the substrate processing module 100. The fluid drain connection 172 is configured to be attached to a process fluid drain conduit (not shown). The process fluid drain conduit enables fluid to be removed from the substrate processing module 100.

One or more guide posts 212 are disposed between a bottom surface 152 of the base body 128 and the support plate 106. The one or more guide posts 212 enable actuation of the base body 128 to pre-set positions and assist in guiding the movement of the base body 128. In one embodiment, the one or more guide posts 212 are disposed on the side of the base body 128 closest to the actuator 110. In some embodiments, a guide post 212 is disposed on either side of the actuator 110 as well as on the opposite side of the base body 128 closest to the fluid supply assembly 122.

FIG. 2 illustrates a schematic side view of the substrate processing module 100. As discussed above, the shaft 148 of the second bearing assembly 108b defines an axis A which extends collinearly along the shaft 148. The axis A serves as an axis of rotation for the processing module 100. The fluid supply assembly 122 also includes a fluid assembly body 206. A first valve actuator 210 and a second valve actuator 208 are coupled to and in communication with the fluid assembly body 206. The first valve actuator 210 and the second valve actuator 208 are configured to open and close valves within the fluid assembly body 206. The first valve actuator 210 and the second valve actuator 208 are pneumatic actuators, but may also be motors, such as a stepper motor, a servo motor, a linear motor, or a direct drive motor.

A vent connector 204 is disposed on top of the upper portion 102, such as on top of the lid 130. The vent connector 204 is coupled to a fluid delivery line (not shown). The vent connector 204 assists in providing a vent to a process volume 404 (FIG. 4). The vent connector 204 can also be used to apply a vacuum to the process volume 404 or pressurize the process volume 404.

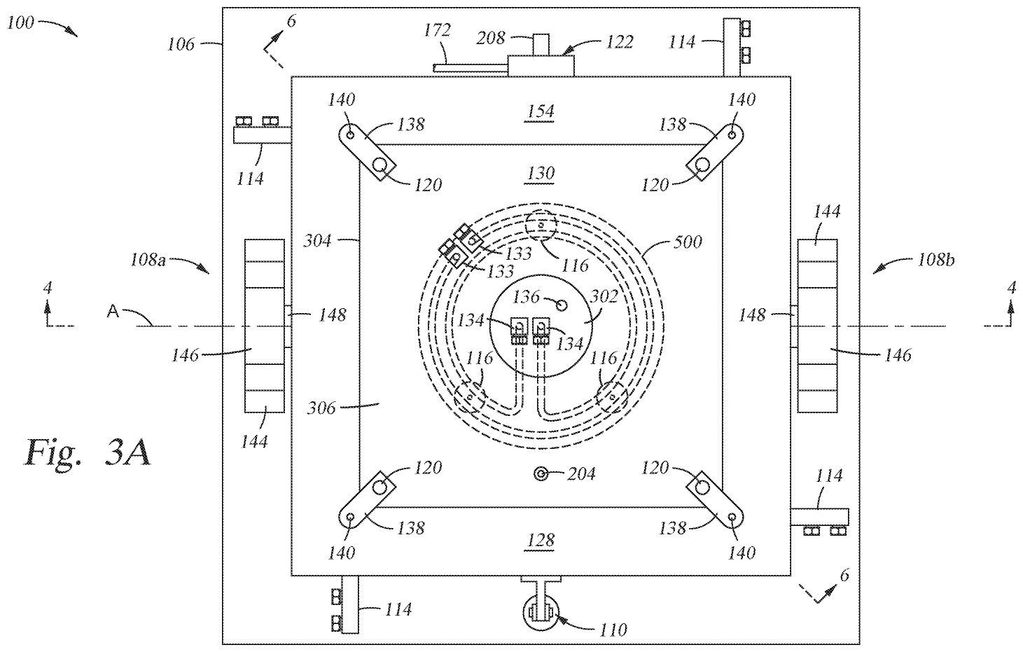

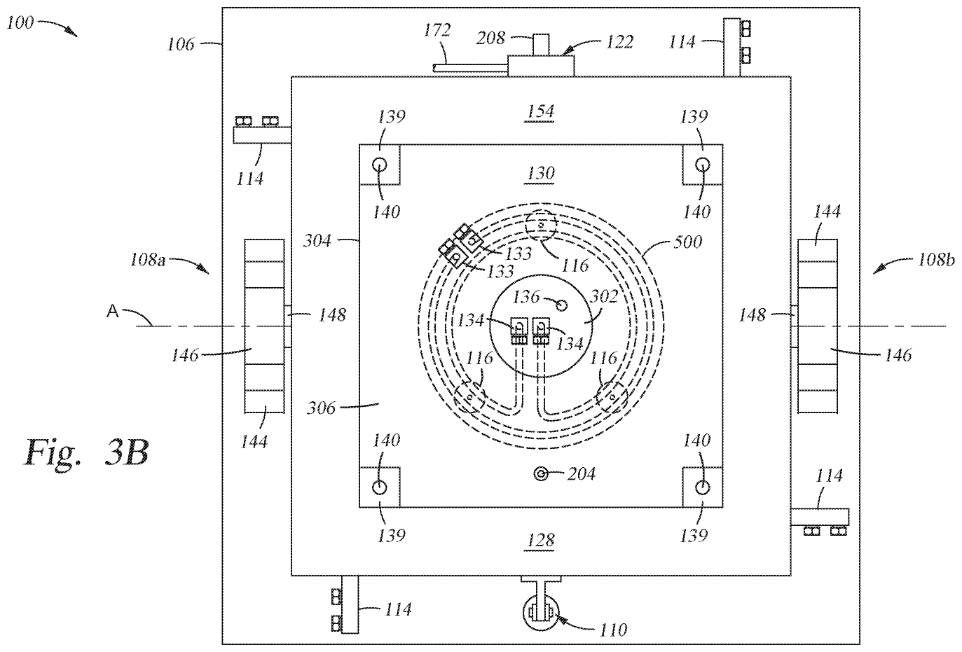

FIG. 3A illustrates a schematic plan view of the substrate processing module 100 of FIG. 1 according to a first embodiment. The processing module 100 of FIG. 3A includes four arms 112 with four shafts 140, and four connection rods 120. Each of the four arms 112 and the connection rods 120 are disposed at corners of the upper portion 102 and the lid 130. Similarly, each of the arm actuator coolant connections 114 is disposed proximate a respective corner of the base body 128. In one embodiment, the vent connection 204 is disposed on a half of the lid 130 closest to the actuator 110. In another embodiment, the vent connection 204 is disposed on a half of the lid 130 opposite the actuator 110. Each of the electrode cooling fluid connections 134 and the electrode connection 136 is disposed within a depression 302 within the lid 130. The depression 302 is a circular depression within the top surface of the lid 130, such that the thickness of the lid 130 decreases at the depression 302.

As shown, each of the first bearing assembly 108a and the second bearing assembly 108b are disposed opposite one another and are mirrored on either side of the lower portion 104.

Within the first embodiment of FIG. 3A, the lid 130 has a smaller top area than the top surface 154 of the base body 128. In the embodiment of FIG. 3A, the shaft 140 of the arms 112 does not pass through the lid 130 and instead is disposed outside the edge 304 of the lid 130. The connection rods 120 are disposed through the lid 130. The fasteners 138 couple each of the connection rods 120 and the shafts 140 together. The fastener 138 additionally couples each of the shafts 140 to the lid 130 to enable lifting and lowering of the lid 130 using the shafts 140. The use of a shaft 140 and a connection rod 120 at each of the corners of the lid 130 enables uniform lifting and lowering of both the lid 130 and the lift pin plate 118. Other arrangements of the shafts 140 and the connection rods 120 are contemplated and may include the use of two or more shafts 140 and connection rods 120, such as three shafts 140 and three connection rods 120.

FIG. 3B illustrates a schematic plan view of the substrate processing module of FIG. 1 according to a second embodiment. The second embodiment is similar to the first embodiment of FIG. 3A, but the shafts 140 of the arms 112 are disposed through the lid 130. The shafts 140 are coupled to the lid 130 at a top surface 306 of the lid 130 by a fastening cap 139. The fastening cap 139 secures each of the shafts 140 to the lid 130. The connection rods 120 are not shown in the embodiment of FIG. 3B, but are disposed radially inward of the shafts 140. The connection rods 120 do not extend fully to the top surface of the lid 130, but are disposed through at least a portion of the upper portion 102. In FIG. 3B, the top surface area of the lid 130 is greater than the top surface area of the lid 130 in the embodiment of FIG. 3A.

FIG. 4 illustrates a schematic cross-sectional view of the substrate processing module of FIG. 1 through a first plane according to one embodiment described herein. The view of FIG. 4 further illustrates the process volume 404, the substrate support surface 406, the electrode 400, the bottom electrode surface 402, a sealing groove 412 disposed around the process volume 404, and a sealing ring 410 disposed within the sealing groove 412. The process volume 404 is a volume for processing of a substrate and is disposed between the upper portion 102 and the lower portion 104. The process volume 404 is formed at least partially by the substrate support surface 406 being vertically offset from the top surface 154 of the base body 128.

The substrate support plate 408 is disposed within the base body 128 and forms a portion of the process volume 404. The substrate support plate 408 is disposed above the chuck isolation plate 126 and the base bottom plate 124. The substrate support plate 408 is configured to be a heated plate and may be grounded by one or more electrical connections 432. The substrate support plate 408 is heated using one or more heating elements 430 disposed therein. In some embodiments, the heating elements 430 are resistive heaters. The heating elements 430 may alternatively be heating pipes or lamps disposed within the substrate support plate 408. The substrate support plate 408 is a conductive material, such as a metal or metal containing material. In some embodiments, the substrate support plate 408 is an aluminum material, a stainless steel material, or alloys thereof. In yet other embodiments, the substrate support plate 408 is formed of a quartz material or a silicon carbide material. The substrate support plate 408 forms the substrate support surface 406. The substrate support surface 406 is a surface disposed on top of the substrate support plate 408 and configured to receive a semiconductor substrate, such as the substrate 500 of FIG. 5A.

A lift pin 416 is disposed through the substrate support plate 408. The lift pin 416 is disposed within an aperture 414 within the substrate support plate 408. As shown in FIG. 5A, each of the lift pins 416 is disposed within a separate aperture 414 to enable the lift pins 416 to be raised and lowered through the substrate support plate 408. In some embodiments, the apertures 414 are also utilized to apply vacuum to the backside of a substrate or to pressurize the backside of the substrate.

The sealing groove 412 is formed in the top surface 154 of the base body 128. In some embodiments, the sealing groove 412 may alternatively be formed in the bottom surface 413 of the spacer plate 132. The sealing groove 412 includes a sealing ring 410 disposed therein. The sealing ring 410 is a polymer, such as a fluoropolymer or a polyaryletherketone (PAEK) material. In some embodiments, the sealing ring 410 is polyether ether ketone (PEEK) or polytetrafluoroethylene material. In some embodiments, the sealing ring 410 is an o-ring, gasket, or other type of seal. The sealing ring 410 forms a seal between the bottom surface 413 of the spacer plate 132 and the top surface 154 of the base body 128 to prevent leakage of fluid from the process volume 404 during processing of a substrate.

In one embodiment, the electrode 400 is a disk disposed above the substrate support surface 406. The electrode 400 is fabricated from an electrically conductive material with an electric resistivity of less than about 1×10⁻³ Ω·m, such as less than 1×10⁻⁴ Ω·m, such as less than 1×10⁻⁵ Ω·m. In some embodiments, the electrode 400 is a metal material, a metal alloy material, or a silicon carbide material. When the electrode 400 is a metal material, the electrode 400 is formed of copper, aluminum, platinum, steel, or combinations thereof. The electrode 400 is electrically coupled to the electrode connection 136 to enable a voltage or a current to be applied to the electrode 400 via a power source (not shown).

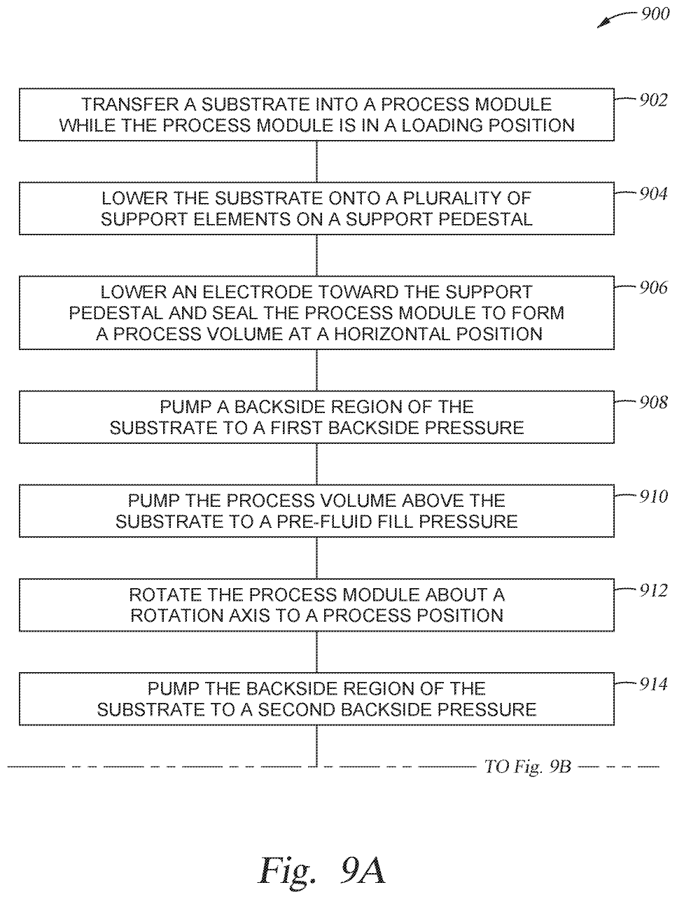

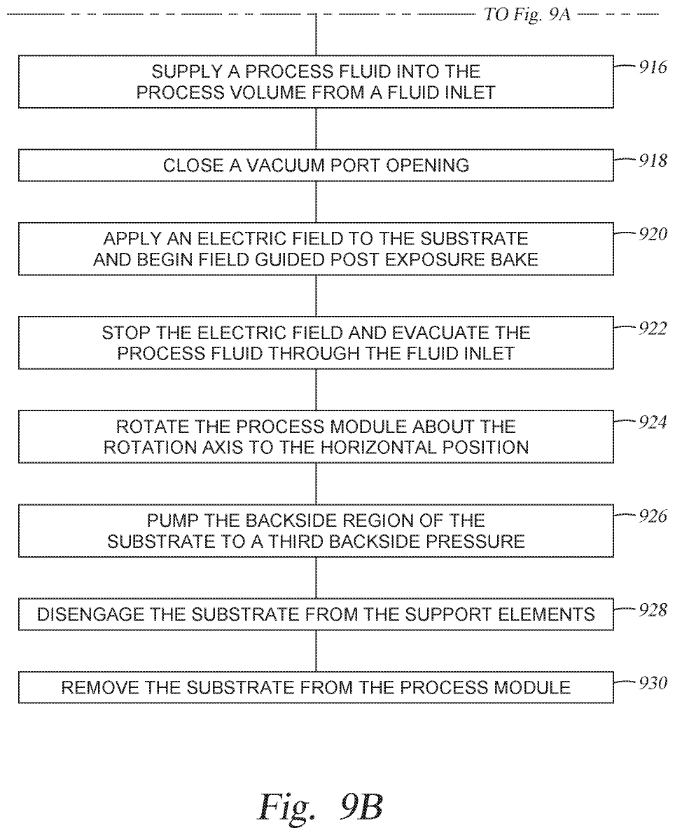

FIGS. 5A-5F illustrate schematic cross-sectional views of the substrate processing module 100 of FIG. 1 through a second plane during different process operations. FIGS. 5A-5F illustrate one embodiment of the process operations of the method 900 of FIGS. 9A and 9B.

As shown in FIGS. 5A-5F, the processing module 100 further includes a fluid inlet passage 508, a vent passage 502, and a vacuum passage 506. Each of the fluid inlet passage 508, the vent passage 502, and the vacuum passage 506 are in fluid communication with the process volume 404. The fluid inlet passage 508 is disposed through the base body 128 and fluidly connects the process volume 404 with the fluid supply assembly 122.

The fluid supply assembly 122 includes a central passage 510 connected to a first branched passage 516 and a second branched passage 518. Each of the first branched passage 516 and the second branched passage 518 are disposed off of the central passage 510. The first branched passage 516 includes a process fluid opening 520 disposed through a sidewall of the first branched passage 516 and a first valve 512. The first valve 512 is coupled to the first valve actuator 210. The first valve actuator 210 is configured to move the first valve 512 to open or close the process fluid opening 520. The process fluid opening 520 is in an open position when in fluid communication with the central passage 510 and in a closed position when the first valve 512 is actuated to a position where the process fluid opening 520 is not in fluid communication with the central passage 510.

Similarly, the second branched passage 518 includes a drain opening 522 disposed through a sidewall of the second branched passage 518 and a second valve 514. The second valve 514 is coupled to the second valve actuator 208. The second valve actuator 208 is configured to move the second valve 514 to open or close the drain opening 522. The drain opening 522 is in an open position when in fluid communication with the central passage 510 and in a closed position when the second valve 514 is actuated to a position where the drain opening 522 is not in fluid communication with the central passage 510. As shown herein, each of the first valve 512 and the second valve 514 are pistons. The first valve 512 is closed when a piston head of the first valve 512 separates the process fluid opening 520 from the central passage 510. The second valve 514 is closed when the piston head of the second valve 514 separates the drain opening 522 from the central passage 510. When in communication with the central passage 510, either of the process fluid opening 520 or the drain opening 522 are in fluid communication with the process volume 404.

The fluid supply connection 170 corresponds to the process fluid opening 520 and supplies process fluid to the process fluid opening 520 when coupled to a process fluid supply (not shown). The fluid drain connection 172 corresponds to the drain opening 522 and removes process fluid via the drain opening 522 when coupled to a process fluid removal device, such as a fluid pump (not shown).

On the opposite side of the process volume 404 from the opening to the fluid inlet passage 508 are openings to the vent passage 502, and the vacuum passage 506. The vent passage 502 extends through the upper portion 102, such that the vent passage 502 is a passage formed through the lid 130 and the spacer plate 502. The vent passage 502 is disposed radially outward of the electrode 400. The vent passage 502 connects the process volume 404 to the vent connector 204. In one embodiment, the vent passage 502 is used to vent excess fluid or gas from the process volume 404. Alternatively, the vent passage 502 is used to form a vacuum within the process volume 404 when the vent passage 502 is in fluid communication with an evacuation pump (not shown).

The vacuum passage 506 extends through the lower portion 104, such that the vacuum passage 506 extends through the base body 128. The vacuum passage 506 fluidly connects the process volume and a vacuum connection 504 disposed on the bottom surface 152 of the base body 128. The vacuum connection 504 is a coupling component configured to be attached to a fluid or a gas line. The vacuum connection 504 in some embodiments is coupled to a vacuum pump for removing gas from the process volume 404. In yet other embodiments, the vacuum connection 504 is configured to be coupled to a fluid pump and is capable or recirculating or removing fluid from the process volume 404 during substrate processing.

The actuator 110 is shown herein as a pneumatic actuator. The actuator 110 includes the opening 524 within the piston 158. The opening 524 includes the actuator shaft 162 disposed therein. The opening 524 is a cylindrical opening and the inner surface 525 of the opening 524 is configured to be a similar size to the head 531 of the actuator shaft 162, such that a pressure differential is achieved between different portions of the opening 524.

As shown in FIG. 5A, the processing module 100 is oriented in a horizontal loading position. The horizontal loading position includes the upper portion 102 and the lift pins 416 being in a raised position. A substrate 500 is placed on top of the lift pins 416 in a raised position. The top distal ends of the lift pins 416 are disposed vertically offset from the substrate support surface 406, such that the top distal ends of the lift pins 416 are above the substrate support surface 406. The processing module 100 is positioned in the horizontal loading position during loading and unloading of the substrate 500 from the processing module 100.

FIG. 5B illustrates the processing module 100 while the upper portion 102 is in an intermediate position. The intermediate position is a position between the loading position and a lowered position. The intermediate position is the position at which the substrate 500 is disposed on the substrate support surface 406 and the upper portion 102 has not formed a seal with the base portion 104 to seal the process volume 404, for example, the upper portion 102 is spaced from and the base portion 104. Between the horizontal loading position and the intermediate position, the electrode 400 and the substrate 500 are lowered at the same rate. After the upper portion 102 has reached the intermediate position, the substrate 500 remains stationary, while the electrode 400 and the other components of the upper portion 102 continue to be lowered to a lowered position as shown in FIG. 5C.

While in the lowered position of FIG. 5C, the bottom surface 413 of the upper portion 102, such as the bottom surface 413 of the spacer plate 132, and the top surface 154 of the base body 128 are in contact and form a seal therebetween using the sealing ring 410. The process volume 404 is sealed from the outside environment by the electrode 400, the substrate support plate 408, the base body 128, and the spacer plate 132. Once the processing module 100 is in the lowered position, the process volume 404 is evacuated or filled with a fluid. The volume between the substrate 500 and the substrate support plate 408 may also have a vacuum applied thereto as described in the method 900 of FIGS. 9A and 9B.

While in the lowered position, the lift pins 416 are spaced from the bottom surface of the substrate 500. The connection of the connection rods 120 with both the lift pin plate 118 and the upper portion 102 continues to lower the lift pins 416 after the substrate 500 has been disposed on the substrate support surface 406 and the upper portion 102 is being lowered. The bellows 116 expand as the lift pins 416 are lowered.

Once the process volume 404 is sealed, the processing module 100 is actuated to a first angled position as shown in FIG. 5D. The first angled position is a position where the upper portion 102 and the base portion 104 of the processing module 100 are angled with respect to a horizontal plane and/or the support plate 106. The upper portion 102 and the base portion 104 are angled by moving the actuator shaft 162 within the piston 158, such that the base portion 104 and the upper portion 102 are rotated about the axis A utilizing the bearing assemblies 108a, 108b.

FIG. 5E illustrates the processing module 100 while the processing module 100 is in the first angled position and filled with a process fluid, such as an intermediate medium or a dielectric liquid. The process fluid is introduced through the process fluid opening 520, which is shown open in FIG. 5E. Excess process fluid 520 and any remaining gases may be vented through the vent passage 502. The vacuum passage 506 is sealed from the process fluid to prevent process fluid from entering a vacuum pump connected to the vacuum passage 506. While in the processing position, the distance H between the top surface of the substrate and the bottom surface of the electrode is about 0.1 mm to about 10 mm, such as about 0.5 mm to about 7 mm, such as about 1 mm to about 5 mm, such as about 1 mm to about 3 mm. The distance H between the top surface of the substrate and the bottom surface of the electrode enables a reduced voltage drop across the gap between the substrate 500 and the electrode 400. Reducing the voltage drop across the gap enables the use of lower voltages during post exposure bake operations.

FIG. 5F illustrates the processing module 100 while the processing module 100 is in the first angled position and the process fluid is being drained through the drain opening 522. As shown in FIG. 5F, the drain opening 522 is in fluid communication with the process volume 404 while the second valve 514 is in an open position.

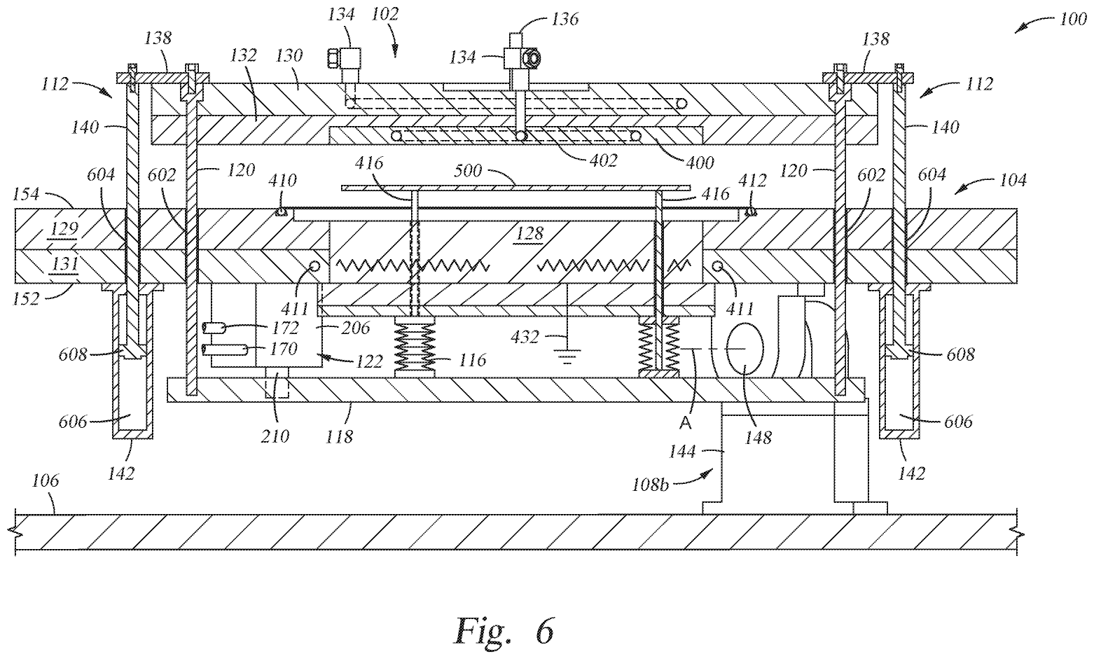

FIG. 6 illustrates a schematic cross-sectional view of the substrate processing module 100 of FIG. 1 through a third plane according to one embodiment described herein. The third plane is a diagonal of the processing module 100. FIG. 6 illustrates connection rod apertures 602, and shaft apertures 604 for the arms 112.

The connection rod apertures 602 enable the connection rods 120 to move freely within the base body 128. The connection rod apertures 602 extend between the top surface 154 of the base body 128 and the bottom surface 152 of the base body 128. One connection rod 120 is disposed within each of the connection rod apertures 602. Each of the connection rod apertures 603 further includes a bearing assembly (not shown) which assists in guiding the connection rod 120 through the connection rod aperture 602. The bearing assembly may be a linear bearing, a ball spline bearing, or other suitable bearing assembly.

The shaft apertures 604 enable the shafts 140 of the arms 112 to move freely within the base body 128. The shaft apertures 604 extend between the top surface 154 of the base body 128 and the bottom surface 152 of the base body 128. One shaft 140 is disposed within each of the shaft apertures 604. The shaft apertures may also include a bearing assembly (not shown) disposed therein. The bearing assembly assists in guiding the shafts 140 through the shaft apertures 604. The bearing assembly may be a linear bearing, a ball spline bearing, or other suitable bearing assembly.

Each of the arm actuators 142 is further illustrated to include an arm actuator opening 606 and a shaft head 608 coupled to each of the shafts 140. The actuator opening 606 is an opening disposed within each of the arm actuators 142. The shaft head 608 and a portion of one of the shafts 140 is disposed within each of the actuator openings 606. The arm actuators 142 as shown in FIG. 6 are pneumatic actuators.

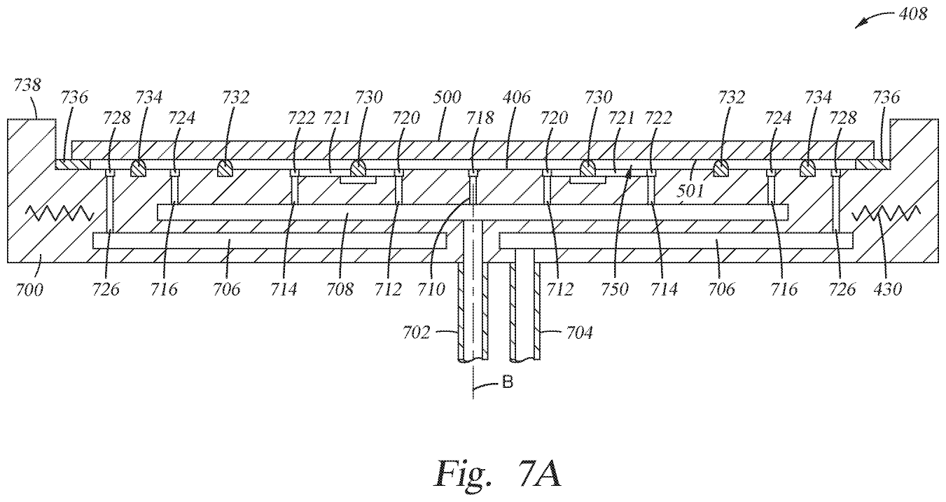

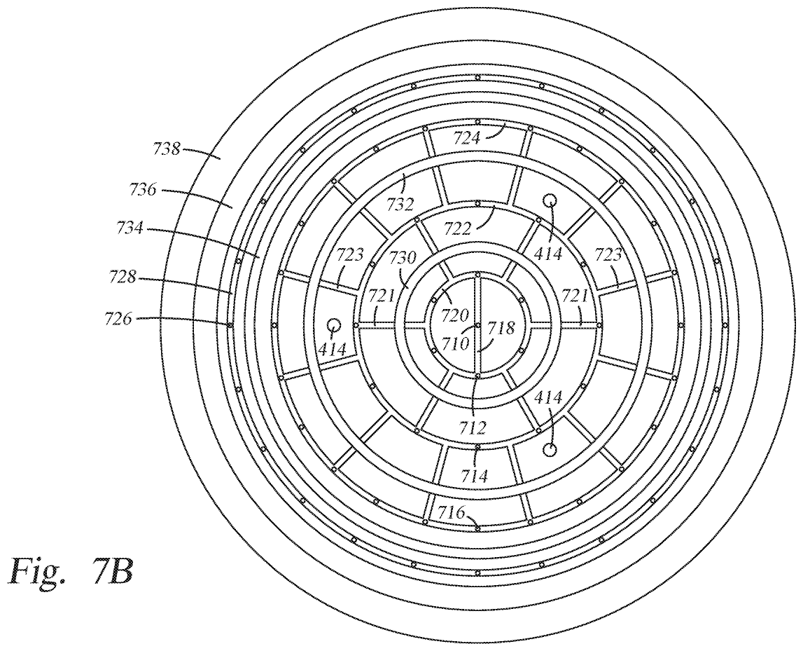

FIG. 7A illustrates a schematic cross-sectional view of a substrate support plate 408 for use with the substrate processing module 100 of FIG. 1 according to one embodiment described herein. The substrate support plate 408 may alternatively be referred to as a substrate chuck or a heated chuck. The substrate support plate 408 includes a chuck body 700. The chuck body 700 includes the substrate support surface 406 disposed therein. The substrate support surface 406 is disposed as the top surface of the chuck body 700. The substrate support surface 406 includes two or more sealing rings 730, 732, 734 disposed on the substrate support surface 406 and a plurality of backside gas channels 718, 720, 722, 724, 728. Each of the plurality of backside gas channels 718, 720, 722, 724, and 728 is fluidly connected to one or more backside gas conduits 706, 708.

Each of the sealing rings 730, 732, 734 is a circular seal disposed on top of or partially embedded within the substrate support surface 406. The sealing rings 730, 732, 734 may also be other shapes, such as an ovoid, elliptical, or linear shape. Other sealing ring shapes are also envisioned. The sealing rings 730, 732, 734 are shown herein as a first sealing ring 730, a second sealing ring 732, and a third sealing ring 734. The sealing rings 730, 732, 734 may also be described as an inner sealing ring, an intermediate sealing ring, and an outer sealing ring, respectively. In this example, a diameter of the second sealing ring 732 is greater than a diameter of the first sealing ring 730 and a diameter of the third sealing ring 734 is greater than the diameter of the second sealing ring 732. Each of the sealing rings 730, 732, 734 is fabricated from a polymer material, such as polyether ether ketone (PEEK) plastic or polytetrafluoroethylene. The sealing rings have a hardness of about 30 durometer to about 120 durometer on the Shore A hardness scale, such as about 45 durometer to about 100 durometer on the Shore A scale, such as about 50 durometer to about 90 durometer on the Shore A scale. Each of the sealing rings 730, 732, 734 may have a modified cross sectional shape to enhance bending of the sealing rings 730, 732, 734 at predetermined pressure conditions. In some embodiments, any or all of the sealing rings 730, 732, 734 have a C-shaped cross section or have a hollow ring cross section. Each of the sealing rings 730, 732, 734 are configured to form a seal between the substrate 500 and the substrate support surface 406.

The sealing rings 730, 732, 734 are configured to deform and enable the bottom surface of the substrate 500 to contact the substrate support surface 406 when the pressure differential between the upper process volume 404 and the volume along the backside 501 of the substrate 500 is increased to a predetermined level. In embodiments described herein, the sealing rings 730, 732, 734 are configured to deform to enable the substrate 500 to contact the substrate support surface 406 when there is a pressure differential of greater than about 75 Torr between the process volume 404 and the volume along the backside 501 of the substrate 500, such as greater than about 90 Torr, such as greater than about 100 Torr. Keeping the substrate 500 from contacting the substrate support surface 406 is beneficial during certain process operations to reduce the rate of temperature increase within the substrate 500. Delaying the contact of the substrate 500 with the substrate support surface 406 delays significant heating of the substrate 500 until the chamber begins or has already been filled with the process fluid and the electric field is activated. The pressure differential between the process volume 404 and the volume along the backside 501 of the substrate 500 is increased when a rapid temperature increase is beneficial within the substrate 500.

The first sealing ring 730, the second sealing ring 732, and the third sealing ring 734 are centered around a central support axis B. The central support axis B is the central axis of the substrate support surface 406. The first sealing ring 730 has a radius of about 0.6 inches to about 2.75 inches, such as about 1 mm to about 2 mm. The second sealing ring 732 has a radius of about 2.75 inches to about 4.5 inches, such as about 3.5 mm to about 4.5 mm. The third sealing ring 734 has a radius of about 4 inches to about 5.5 inches, such as about 4.5 mm to about 5 mm. The central support axis B passes through the central backside gas channel 718. The first backside gas channel 720, the second backside gas channel 722, and the third backside gas channel 724 are centered around the central support axis B. The first backside gas channel 720 has a radius of about 0 mm to about 1.6 mm, such as about 1 mm to about 2 mm. The second backside gas channel 722 has a radius of about 1.75 mm to about 3.75 mm, such as about 2.25 mm to about 3.25 mm. The third backside gas channel 724 has a radius of about 4 mm to about 5 mm, such as about 4.2 mm to about 4.5 mm. The outer backside gas channel 728 has a radius of about 5 mm to about 6 mm, such as about 5.3 mm to about 5.5 mm. The location of each of the sealing rings 730, 732, 734 and each of the backside gas channels 718, 720, 722, 724 are located to control the temperature at the edge of the substrate 500 and to prevent lifting of the substrate edge due to deflection.

The pressure differential between the process volume 404 and the volume 750 along the backside 501 of the substrate 500 is controlled using the backside gas channels 718, 720, 722, 724, 728 and the one or more backside gas conduits 706, 708. A central backside gas channel 718, a first backside gas channel 720, a second backside gas channel 722, a third backside gas channel 724, and an outer backside gas channel 728 are formed in the chuck body 700. Each of the central backside gas channel 718, the first backside gas channel 720, the second backside gas channel 722, and the third backside gas channel 724 are all inner backside gas channels and are configured to be in fluid communication with an inner backside portion of the substrate 500. The outer backside gas channel 728 is disposed radially outward of each of the first backside gas channel 720, the second backside gas channel 722, and the third backside gas channel 724. The outer backside gas channel 728 is disposed between the third sealing ring 734 and an edge support ring 736.

Each of the central backside gas channel 718, the first backside gas channel 720, the second backside gas channel 722, and the third backside gas channel 724 is connected to a first backside gas conduit 708. The first backside gas conduit 708 is fluidly connected to the central backside gas channel 718 via one or more central gas apertures 710. The first backside gas conduit 708 is fluidly connected to the first backside gas channel 720 via one or more first gas apertures 712. The first backside gas conduit 708 is fluidly connected to the second backside gas channel 722 via one or more second gas apertures 714. The first backside gas conduit 708 is fluidly connected to the third backside gas channel 724 via one or more third gas apertures 716. The central gas apertures 710 extend between and connect the central backside gas channel 718 and the first backside gas conduit 708. The first gas apertures 712 extend between and connect the first backside gas channel 720 and the first backside gas conduit 708. The second gas apertures 714 extend between and connect the second backside gas channel 722 and the first backside gas conduit 708. The third gas apertures 716 extend between and connect the third backside gas channel 724 and the first backside gas conduit 708. The first backside gas conduit 708 is fluidly coupled to a backside gas supply connection 702. The backside gas supply connection 702 is disposed on the bottom surface of the chuck body 700 and configured to be attached to a first backside gas supply source (not shown). The backside gas supply connection 702 may also be connected to a first backside pump (not shown) to form a vacuum between the backside of the substrate 500 and the substrate support surface 406.

The central backside gas channel 718 extends across the diameter of the first backside gas channel 720 and connects opposite ends of the first backside gas channel 720. One or more radial gas channels 721 connect the first backside gas channel 720 and the second backside gas channel 722. The one or more radial gas channels 721 extend underneath the first sealing ring 730 and have a greater depth under the first sealing ring 730 to enable fluid communication from the first backside gas channel 720 and the second backside gas channel 722. A similar set of one or more radial gas channels 723 connect the second backside gas channel 722 and the third backside gas channel 724 and has a greater depth under the second sealing ring 732 (FIG. 7B) similar to the first radial gas channels 721.

The first sealing ring 730 is disposed between the first backside gas channel 720 and the second backside gas channel 722. The second sealing ring 732 is disposed between the second backside gas channel 722 and the third backside gas channel 724. The third sealing ring 734 is disposed between the third backside gas channel 724 and the outer backside gas channel 728.

The outer backside gas channel 728 is connected to a second backside gas conduit 706 disposed through the chuck body 700. The second backside gas conduit 706 is coupled to the outer backside gas channel 728 using one or more outer gas apertures 726. The outer gas apertures 726 provide fluid communication between the second backside gas conduit 706 and the outer backside gas channel 728. Each of the first backside gas channel 720, the second backside gas channel 722, the third backside gas channel 724, and the outer backside gas channel 728 are ring shaped and form grooves around the substrate support surface 406.

The second backside gas conduit 706 is fluidly coupled to a second backside gas supply connection 704. The second backside gas supply connection 704 is disposed on the bottom surface of the chuck body 700 and configured to be attached to a second backside gas supply source (not shown). The second backside gas supply connection 704 may also be connected to a second backside pump (not shown) to form a vacuum between the backside of the outer edge of the substrate 500 and the substrate support surface 406.

The edge support ring 736 is disposed radially outward of the outer backside gas channel 728. In one embodiment, the edge support ring 736 is a similar material as the two or more sealing rings 730, 732, 734. In some embodiments, the edge support ring 736 is the same material as the chuck body 700. The edge support ring 736 is positioned to support the outermost edge of the substrate 500. The edge support ring 736 assists in forming a seal between the outer edge of the substrate 500 and the substrate support surface 406.

The chuck body 700 includes a raised edge 738 disposed around the substrate support surface 406. The raised edge 738 forms the depression in which the substrate support surface 406 is disposed. The edge support ring 736 has an outer diameter which is less than an inner diameter of the raised edge 738 such that the edge support ring 736 is disposed on the support surface 406 radially inward of the raised edge 738.

FIG. 7B is a plan view of a substrate support plate 408 for use with the substrate processing module 100 of FIG. 1 according to one embodiment described herein. The substrate 500 is not shown in FIG. 7B. FIG. 7B further illustrates the distribution of the gas apertures 710, 712, 714, 716, and 726 with respect to the backside gas channels 718, 720, 722, 724, 728. The gas apertures 710, 712, 714, 716, and 716 are distributed around the circumference of each of the backside gas channels 718, 720, 722, 724, 728. The first sealing ring 730 is disposed over a portion of the one or more radial gas channels 721 and the second sealing ring 732 is disposed over a portion of another set of one or more radial gas channels 723.

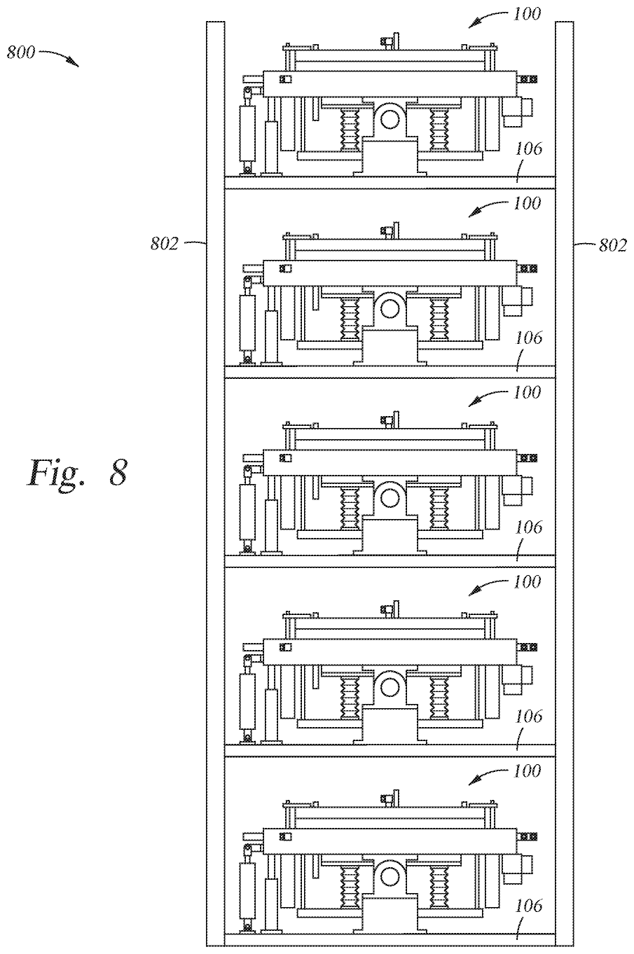

FIG. 8 is a schematic side view of a stacked assembly 800 of substrate processing modules 100 according to one embodiment described herein. The stacked assembly 800 includes a plurality of processing modules 100 disposed over one another in a vertical stack. As shown herein, the support plate 106 of each of the processing modules 100 is attached to a support railing 802. The support railing 802 is a vertically oriented pole or support structure. The substrate plate 106 may slide into and connect to each of the support railings 802 to secure the processing modules 100 in place. As shown herein, there are five processing modules 100 stacked over one another. The clearance between the top of each of the processing modules 100 and the bottom of the support plate 106 over the processing module 100 is less than about 18 inches, such as less than about 15 inches, such as about 9 inches to about 15 inches, such as about 11 inches to about 13 inches. The stacking of the processing modules 100 enables increased throughput by processing substrates, such as the substrate 500, within each of the processing modules 100 while reducing the horizontal footprint of a processing system track. The clearance between each of the processing modules 100 enables rotation of the processing modules 100 as described in the method 900 of FIGS. 9A-9B without one of the processing modules 100 contacting the support plate 106 of an adjacent processing module 100.

FIGS. 9A-9B illustrate operations of a method 900 for performing an immersion field-guided post exposure bake process according to an embodiment described herein. The method 900 is performed using the apparatus of FIGS. 1-8, among others. The method 900 includes operation 902 of loading a substrate, such as the substrate 500, into a process module, such as the processing module 100. Loading the substrate into the process module is performed while the processing module 100 is in a horizontal loading position as shown in FIG. 5A. The substrate is placed on lift pins, such as the lift pins 416, by a robot or indexing assembly (not shown). After the substrate is placed on the lift pins, the substrate is lowered onto a plurality of support elements on a substrate support plate, such as the substrate support plate 408, during operation 904. The plurality of support elements includes the sealing rings 730, 732, 734, and the edge support ring 736. The substrate is lowered toward the substrate support surface 406 on the lift pins as shown in FIG. 5B. During loading of the substrate into the processing module 100, the upper portion 102 and the base portion 104 are disposed on a horizontal position. The upper portion 102 and the base portion 104 being in a horizontal position enables the substrate to be loaded into the base portion 104 while the substrate is horizontally oriented.

After loading the substrate during operation 902 and operation 904, an electrode and an upper assembly, such as the upper portion 102, are lowered towards a base assembly, such as the base portion 104. Lowering the electrode and the upper assembly forms a process volume, such as the process volume 404. After operation 904, the upper portion is moved to a lowered position during operation 906 as shown in FIG. 5C. Closing the upper assembly and the base assembly forms a seal between the upper assembly and the base assembly. Forming the seal between the upper assembly and the base assembly enables a process fluid to fill the process volume between the electrode assembly and the base assembly during later operations. The seal also enables the process volume to be evacuated and maintained under a vacuum or at a desired pressure.

During operation 908, a backside region of the substrate is pumped or otherwise reduced to a first backside pressure. The first backside pressure is a pressure in the range of about 75 Torr to about 150 Torr, such as about 90 Torr to about 110 Torr. The backside pressure is sufficient to chuck the substrate to the support elements while not bringing the substrate to contact the substrate support surface. In some embodiments, both the pressure within the main portion of the process volume and the backside pressure are manipulated. The pressure within the process volume and the backside pressure and brought to a pressure wherein the pressure differential between the process volume and the volume along the backside of the substrate is about 1 Torr to about 50 Torr, such as about 5 Torr to about 20 Torr, such as about 5 Torr to about 10 Torr. The backside region of the substrate is pumped using one or more pump assemblies or gas assemblies attached to a backside gas connection, such as the backside gas supply connection 702. The backside region as described herein includes the regions inward of the outermost sealing ring, such as the third sealing ring 734.

In some embodiments, the pressure maintained within the process volume is at or close to atmospheric pressure. For example, the pressure within the process volume is about 600 Torr to about 800 Torr, such as about 700 Torr to about 800 Torr, such as about 750 Torr. When the pressure within the process volume is close to atmospheric pressure, the first backside pressure is about 400 Torr to about 650 Torr, such as about 500 Torr to about 600 Torr, such as about 550 Torr to about 600 Torr. The deduction of the backside pressure from atmospheric pressure to the first backside pressure creates a pressure differential between the process volume and the volume along the backside of the substrate. In embodiments where the pressure within the process volume is closer to atmospheric pressure, the pressure differential between the process volume and the volume along the backside of the substrate is less than about 250 Torr, such as about 0 Torr to about 250 Torr, such as about 1 Torr to about 200 Torr, such as about 5 Torr to about 200 Torr. The pressure differential is great enough to hold the substrate in place on the substrate support surface during the tilting operation 912 described herein. However, the pressure differential is small enough and the sealing rings are configured to keep the backside of the substrate separated from contacting the substrate support surface during the operation 908 to reduce the heating rate of the substrate.

Either simultaneously with or after operation 908, operation 910 of pumping the process volume above the substrate is performed. During operation 910, the process volume above and around the substrate is pumped to a pre-fluid fill pressure. The pre-fluid fill pressure is a pressure of about 175 Torr to about 250 Torr, such as about 195 Torr to about 225 Torr, such as about 200 Torr to about 210 Torr. The pressure along the backside of the substrate may be simultaneously reduces, such that once the process volume had been brought to the pre-fluid fill pressure, the pressure differential between the process volume and the volume along the backside of the substrate is still about 1 Torr to about 50 Torr, such as about 5 Torr to about 20 Torr, such as about 5 Torr to about 10 Torr. The process volume is pumped using a vacuum pump fluidly coupled to one of a vent connection or a vacuum connection, such as the vent connection 204 and the vacuum connection 504.

In some embodiments, the pre-fluid fill pressure is at or close to atmospheric pressure, such as about 600 Torr to about 800 Torr, such as about 700 Torr to about 800 Torr, such as about 750 Torr. Near-atmospheric pre-fluid fill pressures reduce the pump times and increase throughput. In embodiments wherein the pre-fluid pressure is close to atmospheric pressure, there may not be an operation 910 for pumping the process volume above the substrate.

After operation 910, the process module is rotated about a rotation axis, such as the axis A of FIGS. 2-6. The process module is rotated using one or more actuators, such as the actuator 110. One or more bearings, such as the bearings 108a, 108b are utilized to assist in the rotation of the process module about the rotation axis. The process module is rotated to a process position during operation 912. Operation 912 brings the substrate support surface and a bottom surface of the electrode to an angle of about 5 degrees to about 60 degrees, such as about 5 degrees to about 45 degrees, such as about 10 degrees to about 30 degrees with respect to a horizontal plane. The positioning of the processing module and the substrate during operation 912 is illustrated in FIG. 5D. In embodiments described herein the horizontal plane is the orientation of the substrate support surface and the bottom surface of the electrode while in the lowered position and the horizontal loading position. The horizontal plane is the plane of the top surface of a support plate, such as the support plate 106. Rotating the substrate support surface and the bottom surface of the electrode to an angle such as that described above has been found to assist in fluid introduction with reduced bubbling into the process volume between the substrate and the electrode. The angled orientation additionally assists in removing fluid from the process volume.

Either concurrently with or after operation 912, operation 914 is performed. Operation 914 includes pumping or otherwise reducing the backside region of the substrate to a second backside pressure. The second backside pressure is a pressure of about 0 Torr to about 20 Torr, such as about 0 Torr to about 15 Torr, such as about 5 Torr to about 10 Torr. Once the backside region has been brought to the second backside pressure, the pressure differential between the process volume and the volume along the backside of the substrate is about 75 Torr to about 125 Torr, such as about 90 Torr to about 110 Torr. The second backside pressure is less than the first backside pressure. The second backside pressure is a vacuum strong enough to cause the substrate to contact the substrate support surface and reduces shifting of the substrate as process fluids are introduced into the process volume during operation 916. Contacting the substrate support surface causes the substrate to be heated by the substrate support plate. Rapid heating of the substrate by the substrate support plate is therefore delayed until after the pressure along the backside of the substrate is brought to the second backside pressure. Once the pressure is reduced to the second backside pressure, the substrate is heated at a rate of about 4° C./s to about 20° C./s, such as about 5° C./s to about 15° C./s, such as about 6° C./s to about 10° C./s. The substrate is heated to a temperature of about 40° C. to about 250° C., such as about 80° C. to about 230° C., such as about 90° C. to about 130° C. The heat is applied using one or more heating elements, such as the one or more heating elements 430.

In embodiments where the pressure within the process volume is at or close to atmospheric pressure as described with respect to operation 908, the second backside pressure is about 250 Torr to about 450 Torr, such as about 300 Torr to about 400 Torr, such as about 325 Torr to about 375 Torr. The reduction of the backside pressure from first backside pressure to the second backside pressure creates a greater pressure differential between the process volume and the volume along the backside of the substrate. As described above, the second backside pressure is a vacuum strong enough to cause the substrate to contact the substrate support surface and increase the rate of substrate heating. In the embodiment where the pressure within the process volume is closer to atmospheric pressure, the pressure differential between the process volume and the volume along the backside of the substrate is less than about 450 Torr, such as about 100 Torr to about 450 Torr, such as about 200 Torr to about 450 Torr, such as about 300 Torr to about 450 Torr.

Operation 916 is performed either before, during, or after operation 914. In some embodiments, operation 916 is performed immediately after operation 912 and before operation 914. Operation 916 includes supplying a process fluid into the process volume from a fluid inlet, such as the fluid inlet passage 508. The process fluid is dispensed into the process volume using the apparatus of FIGS. 1-6. The process volume is filled with the process fluid. The process fluid is injected into the process volume and fills the process volume in less than 4 seconds, such as less than 3 seconds, such as less than 2 seconds. To fill the process volume, the process fluid is injected into the process volume at a rate of about 5 L/minute to about 20 L/minute, such as about 10 L/minute to about 15 L/minute. In embodiments described herein, the process volume has a volume of about 0.4 L to about 0.6 L, such as about 0.5 L. The process fluid is an intermediate medium, such as a non-gas phase medium, a slurry, a gel, a liquid solution, or a solid state medium that may efficiently maintain voltage levels as applied at a determined range when transmitting from the electrode assembly to the photoresist layer disposed on the substrate. The processing module during operation 916 is illustrated in FIG. 5E.

Once the process fluid has filled the process volume, the vacuum port opening is closed to prevent process fluid from entering the vacuum pump during operation 918. After the vacuum port opening is closed during operation 918, any excess gas or process fluids are vented via a vent passage, such as the vent passage 502.

Either during or after operation 916 and operation 918, an electric field is applied to the substrate by the electrode and the substrate support surface during operation 920. Applying the electric field to the substrate causes the substrate to be processes in a field guided post exposure bake. The electric field is distributed between the substrate, which is held at a first voltage, and the electrode, which is held at a second voltage different from the first voltage. The electric field is created by applying a voltage differential of up to about 5000 V, such as up to about 3500 V, such as up to about 3000 V. The electric field between the electrode and the substrate is less than about 1×10⁷ V/m, such as less than 1×10⁶ V/m, such as less than 1×10⁵ V/m. The electric field may be about 1×10⁵ V/m to about 1×10⁷ V/m, such as about 1×10⁵ V/m to about 1×10⁶ V/m. The strength of the electric field is limited by the breakdown voltage of the medium disposed within the process volume. In some embodiments, the breakdown voltage of the fluid disposed within the process volume is about 1.4×10⁷ V/m. The electric field is applied to the substrate until the post exposure bake operation is complete. Heating is halted when the post exposure bake operation is completed. The substrate and the processing module are held in a position similar to that shown in FIG. 5E during operation 920. In some embodiments the voltage is varied across the surface of the electrode throughout operation 920. The voltage may be varied by alternating the voltage wave forms, the magnitude of the voltage differential, or the location of varying voltage differentials. In some embodiments, current applied to the electrode is varied as opposed to the voltage differential. The current may be similarly varied across the surface of the electrode and may include different waveforms. The current may be applied as an AC or a DC current.

After operation 920, the electric field generation is stopped and the process fluid is evacuated from the process volume through the fluid inlet during operation 922. Evacuating the process fluid from the process volume during operation 922 includes introducing a gas, such as a purge gas via one of the vent passage or the vacuum passage. During operation 922, the vacuum passage is re-opened. Introducing the gas into the process volume while removing the process fluid may increase the rate of process fluid removal and reduce the amount of residual process fluid present after operation 922. During operation 922 the angle of the process module with respect to the horizontal may increase. The increased angle of the process module with respect to the horizontal includes increasing the angle of the substrate support surface and the bottom of the electrode with respect to the top surface of the top surface of the support plate. The increased angle may be referred to as a drain angle. The drain angle is about 5 degrees to about 60 degrees, such as about 5 degrees to about 45 degrees. The evacuation of the process fluid from the process volume is illustrated in FIG. 5F.

Either simultaneously with or after operation 922, operation 924 is performed. Operation 924 includes rotating the process module back to the horizontal position about the rotation axis. The rotating the process module back to the horizontal position includes rotating the process module such that the substrate support surface and the bottom surface of the electrode are parallel with the top surface of the support plate. Rotating back to the horizontal position enables the substrate to be unloaded in subsequent operations using the same horizontal robot arm or indexer used during operation 902.

After operation 924, the backside region of the substrate is pumped to a third backside pressure during operation 926. During operation 926, the third backside pressure is about 300 Torr to about 9000 Torr, such as about 400 Torr to about 850 Torr, such as about 450 Torr to about 550 Torr. The third backside pressure is greater than the first backside pressure or the second backside pressure. The third backside pressure is an increase in pressure to allow the substrate to be de-chucked from the substrate support surface and the substrate support plate. In some embodiments, the third backside pressure is greater than the pressure within the process volume to create an upward force and move the substrate away from the substrate support surface. Once the backside region of the substrate is brought to the third backside pressure, the pressure differential between the process volume and the volume along the backside of the substrate is about −200 Torr to about 200 Torr, such as about −100 Torr to about 100 Torr.

In embodiments where the process volume is close to atmospheric pressure, such as about 600 Torr to about 800 Torr, the third backside pressure is similarly at, close to, or greater than atmospheric pressure. Therefore, during operation 926, the backside pressure is close enough to the pressure within the process volume to enable lifting of the substrate using the lift pins while reducing damage to the backside of the substrate. The pressure differential may be less than 100 Torr, such as less than 50 Torr. In some embodiments, the backside pressure during operation 926 is greater than atmospheric pressure to cause the substrate to be “ejected” from the substrate support surface by the sealing rings and the lift pins.

Operation 928 is performed either simultaneously with or after operation 926. Operation 928 includes actuating the upper assembly and the base assembly back an open position. As the upper assembly is actuated upward to the open position, the substrate is disengaged from the support elements on the substrate support surface by the lift pins. The substrate is lifted to a position similar to that shown in FIG. 5A. Actuating the upper assembly and the base assembly to the open position involves separating the sealing surfaces of the upper assembly and the base assembly.

After operation 928, the substrate is removed from the processing module during operation 930. The substrate is removed using an indexer or robot arm and transferred to a different processing module or process station.

Embodiments described herein are beneficial in that substrates may be processed horizontally, while reducing bubbling effects on the post exposure bake process. Embodiments described herein also allow for the electrodes and substrate to be disposed closer together during processing, which reduces the impact of electric field non-uniformities. The use of the transfer device with a plurality of openings for the pedestals further enables a plurality of substrates to be processed at a time with shared apparatus. This increases throughput of the system and decreases cost of ownership.

While the foregoing is directed to embodiments of the present disclosure, other and further embodiments of the disclosure may be devised without departing from the basic scope thereof, and the scope thereof is determined by the claims that follow.

What is claimed is:

1. A substrate processing apparatus, comprising:
a support plate;
a base portion disposed on top of the support plate, the base portion comprising:
a base body;
a substrate support plate disposed within the base body;
a substrate support surface on the substrate support plate;
one or more bearings coupled to the base body and configured to rotate the base body about an axis; and
an actuator coupled to the base body and the support plate;
an upper portion disposed above the base portion and the support plate, the upper portion comprising:
an electrode; and
a lid disposed above the electrode; and
a plurality of arms connecting the upper portion and the base portion.

2. The substrate processing apparatus of claim 1, wherein each of the plurality of arms comprises:
an arm actuator disposed below the base body; and
a shaft disposed through a portion of the arm actuator and the base body, the shaft coupled to the upper portion and configured to raise or lower the upper portion with respect to the base body.

3. The substrate processing apparatus of claim 1, wherein the one or more bearings comprise two pillow block bearings, each of the pillow block bearings further comprising:
a housing disposed on the support plate; and
a bearing shaft disposed through the housing and coupled to the base portion, such that as the bearing shaft rotates within the housing.

4. The substrate processing apparatus of claim 1, further comprising:
a plurality of lift pins disposed through the base body and the substrate support plate;
a lift pin plate disposed below the base body and configured to support each of the plurality of lift pins; and
a lift pin bellows assembly disposed between the lift pin plate and the base body and surrounding a portion of the plurality of lift pins.

5. The substrate processing apparatus of claim 1, wherein the substrate support plate is a heated plate with one or more heating elements disposed therein.

6. The substrate processing apparatus of claim 1, wherein the substrate support plate is a second electrode disposed opposite the electrode of the upper portion.

7. The substrate processing apparatus of claim 1, wherein the actuator is configured to raise a side of the base body closest to the actuator and tilt the base body.

8. The substrate processing apparatus of claim 7, wherein the actuator is a pneumatic actuator.

9. A substrate processing apparatus, comprising:
a support plate;
a substrate processing module comprising:
a base portion disposed on top of the support plate, the base portion comprising:
a base body;
a substrate support plate disposed within the base body;
a substrate support surface on the substrate support plate;
an upper portion disposed above the base portion and the support plate, the upper portion comprising:
an electrode with a bottom surface disposed parallel to the substrate support surface; and
a lid disposed above the electrode; and
a plurality of arms connecting the upper portion and the base portion;
an actuator coupled to the base body and the support plate;
one or more bearings coupled to the base body and configured to rotate the base body about an axis as the actuator moves the base body; and
a fluid inlet disposed through the base body.

10. The substrate processing apparatus of claim 9, wherein the substrate support plate further comprises:
two or more sealing rings disposed on the substrate support surface;
a backside gas conduit; and
a plurality of backside gas channels disposed along the substrate support surface and in fluid communication with the backside gas conduit.

11. The substrate processing apparatus of claim 9, further comprising a fluid delivery system fluidly coupled to the fluid inlet, the fluid delivery system comprising:
a fluid supply valve; and
a fluid drain valve.

12. The substrate processing apparatus of claim 9, wherein the fluid inlet is in fluid communication with a process volume, the process volume formed between the base portion and the upper portion when the upper portion is lowered to a processing position.

13. The substrate processing apparatus of claim 12, wherein an outlet is disposed on the opposite side of the process volume from the fluid inlet through the base portion.

14. The substrate processing apparatus of claim 13, wherein a vent conduit is disposed on the opposite side of the process volume from the fluid inlet through the upper portion.

15. The substrate processing apparatus of claim 12, wherein a sealing groove is disposed within a sealing surface base portion and around the process volume.

16. The substrate processing apparatus of claim 9, wherein fluid inlet is disposed on an opposite side of the axis from the actuator.

17. A method of processing a substrate comprising:
position a substrate onto a substrate support plate while the substrate support plate is in a first position;
moving an electrode towards the substrate support plate to form a process volume around the substrate and between the electrode and the substrate support plate;
pumping a backside of the substrate to a first backside pressure;
rotating the process volume about a rotation axis to a process position using an actuator;
pumping a backside of the substrate to a second backside pressure less than the first backside pressure;
suppling a process fluid to the process volume from a fluid inlet after rotating the process volume to the process position and pumping the backside of the substrate to the second backside pressure;
applying an electric field to the substrate using the electrode while in the process position; and
draining the process fluid from the process volume while in the process position.

18. The method of claim 17, wherein rotating the process volume about the rotation axis to the process position comprises:
rotating the process position about 5 degrees to about 60 degrees from the first position.

19. The method of claim 17, wherein applying an electric field further comprises:
applying the electric field between parallel surfaces of the electrode and the substrate support plate.

20. The method of claim 17 further comprising:
reducing, the pressure of the process volume to a first process volume pressure before supplying the process fluid to the process volume.
